(19) United States
(12) Patent Application Publication
(10) Pub. No.: US 2024/0429071 A1
(43) Pub. Date: Dec. 26, 2024

(54) THERMAL LEVELER BLANK FOR INTEGRATION WITH THERMAL MANAGEMENT

(71) Applicant: MOMENTIVE PERFORMANCE MATERIALS QUARTZ, INC., Strongsville, OH (US)

(72) Inventors: Matthew Peter Gallaugher, Middleburg Heights, OH (US); Anand Murugaiah, Brunswick, OH (US); Dhavalkumar Patel, Strongsville, OH (US); David Sabens, Solon, OH (US); Jefferson E. Troha, Cleveland, OH (US); ISMAIL NAS, STRONGSVILLE, OH (US)

(21) Appl. No.: 18/750,242

(22) Filed: Jun. 21, 2024

Related U.S. Application Data
(60) Provisional application No. 63/522,871, filed on Jun. 23, 2023.

(51) Int. Cl. H01L 21/67; F28F 21/08

(52) U.S. Cl. CPC H01L 21/67103; F28F 21/089

(57) ABSTRACT

A thermal leveler blank is provided. The thermal leveler blank includes a first encapsulating layer, a second encapsulating layer, and a thermal spreader layer. The second encapsulating layer is arranged over the first encapsulating layer. The thermal spreader layer is sandwiched between the first encapsulating layer and the second encapsulating layer. Each of the first encapsulating layer and the second encapsulating layer have substantially planar outermost surfaces that are free of thermal control structures.

### RELATED APPLICATIONS

This application claims the benefit of and priority to U.S. Provisional Application No. 63/522,871 filed on Jun. 23, 2023, which is hereby incorporated herein by reference in its entirety.

### TECHNICAL FIELD

In general, the present disclosure relates to a thermal leveler and a thermal leveler blank and, more particularly, to a thermal leveler blank that includes thermally conductive material that can be post-processed using standard manufacturing processes to include structural features such as, for example, heating and/or cooling structures, backside gas channels, lift pins, mesas, and other surface patterning.

### BACKGROUND OF THE INVENTION

In semiconductor processing, having uniform heat applied to the wafer during various processing such as epitaxy is highly desirable. Additionally, heat may be undesirably generated in electronics and electrical systems, including semiconductor applications and systems comprising processors, circuits, displays, power storage units, and the like, for example. Thermal management of these electronics and electrical systems is important to ensure proper operation, safety, longevity, and undiminished performance over the lifetime of the systems.

### SUMMARY OF THE INVENTION

In accordance with an embodiment, a thermal leveler blank is provided. The thermal leveler blank includes a first encapsulating layer, a second encapsulating layer, and a thermal spreader layer. The second encapsulating layer is arranged over the first encapsulating layer. The thermal spreader layer is sandwiched between the first encapsulating layer and the second encapsulating layer. The thermal leveler blank is strong enough to be further machined in a secondary manufacturing step to implement custom thermal control structures on at least one of the first or second encapsulating layers.

These and other aspects will be evident when viewed in light of the drawings, detailed description and appended claims.

### BRIEF DESCRIPTION OF THE DRAWINGS

Various non-limiting embodiments may take physical form in certain parts and arrangements of parts, which will be described in detail in the specification and illustrated in the accompanying drawings which form a part hereof, and wherein:

FIG. 1 illustrates a cross-sectional view of some embodiments of a thermal leveler blank as described further herein.

FIGS. 2A and 2B illustrate a cross-sectional view of some other embodiments of a thermal leveler blank as described further herein.

FIG. 3 illustrates a partial perspective view of some embodiments of a semiconductor wafer arranged over a thermal leveler blank as described further herein.

FIG. 4 illustrates a cross-sectional view of some embodiments of a thermal leveler comprising a heat spreader layer and a thermal management structure embedded within bonded encapsulant structures as described further herein.

FIG. 5 illustrates a cross-sectional view of some other embodiments of a thermal leveler that is formed by machining a frontside and a backside of a thermal leveler blank as described further herein.

FIGS. 6, 7, 8, and 9A illustrate cross-sectional views of various other embodiments of a thermal leveler blank as described further herein.

FIGS. 9B and 9C illustrate various views of some embodiments of a thermal leveler having support vias and a thermal control structure as described further herein.

FIGS. 10A, 10B, 11A, 11B, 12A, 12B, 13, 14, 15A, 15B, 16, and 17 illustrate a method of forming some embodiments of a thermal leveler blank and a thermal leveler formed from machining the thermal leveler blank as described further herein.

FIG. 18 illustrates a flow diagram of some embodiments of a method of forming a thermal leveler blank and a thermal leveler formed therefrom as described in FIGS. 10-17.

### DETAILED DESCRIPTION OF THE INVENTION

In semiconductor manufacturing, wafers are placed on a substrate holder within various processing chambers for deposition of layers on the wafer, removal/etching of layers on the wafer, dicing of the wafer, and the like. To ensure uniformity of the deposition and/or removal of layers on the wafer, the surrounding conditions such as temperature, air pressure, and the like are controlled. In some embodiments, the substrate holder is heated or cooled through various thermal management structures embedded within and/or surrounding the substrate holder. For example, in some embodiments, thermal spreader layers are used to dissipate, level, spread, and/or focus heat within certain areas of an object or environment. In addition to semiconductor manufacturing, thermal spreader layers may be used to provide thermal management in electronics and electrical systems.

Thermal spreaders may be used to transfer heat from a concentrated heat source or hotter medium to a secondary heat exchanger or cooler medium. In some semiconductor processing applications, the thermal spreaders can help to dissipate the heat in the lateral direction and improve the temperature distribution across an entire wafer substrate. Thermal spreaders may utilize materials having a high thermal conductivity and achieve a desired temperature profile utilizing the enhanced thermal conductivity of the materials. Conventional thermal spreaders may utilize copper, aluminum, molybdenum-copper, and other materials having high thermal conductivities.

Various embodiments of the disclosure relate to forming thermal leveler blanks having a thermal spreader layer embedded within an encapsulant assembly. The thermal spreader layer may, in some embodiments, be thermal pyrolytic graphite, which has high thermal conductivity, low thermal interface resistance, and low weight. In particular, at least one side of the encapsulant structure surrounding the thermal spreader layer has an increased thickness relative to the heat spreader layer. This side is thick enough and strong enough to withstand further machining to embed other structures within the thermal leveler blank, such as, but not limited to, heating coils, cooling gas lines, cooling water lines, or other thermal control structures, without compromising the integrity of thermal spreader layer.

This way, semiconductor manufacturers may purchase a universal thermal leveler “blank” that is ready for machining custom patterns into the thermal leveler blank using common machining methods such as chemical mechanical planarization (CMP), cutting, milling, etching, and the like. After these post-processing and machining steps on the blank, the thermal leveler may include surface textures, features, structures, cutouts, and/or channels or patterns, such as, but not limited to, for the integration of heating elements or cooling channels, mesas, backside gas channels, and other surface patterning and textures, such as for lift pins. By machining these patterns in-house, semiconductor manufacturers may save costs while still using integrating specialized materials such as thermal pyrolytic graphite into semiconductor processing chambers to provide high temperature uniformity and/or zone control for heaters, cold plates, and/or other thermal management applications within the processing chambers. In some embodiments, the disclosed thermal leveler has a significant improvement (about 2-times better) in temperature uniformity across the thermal leveler using a single heating zone when compared to a coiled heater without thermal pyrolytic graphite. Azimuthal temperature variations are also reduced with the disclosed thermal leveler.

With reference to the drawings, like reference numerals designate identical or corresponding parts throughout the several views. The inclusion of like elements in different views, however, does not mean a given embodiment necessarily includes such elements or that all embodiments include such elements. The examples and figures are illustrative only and not meant to be limiting of the claimed subject matter.

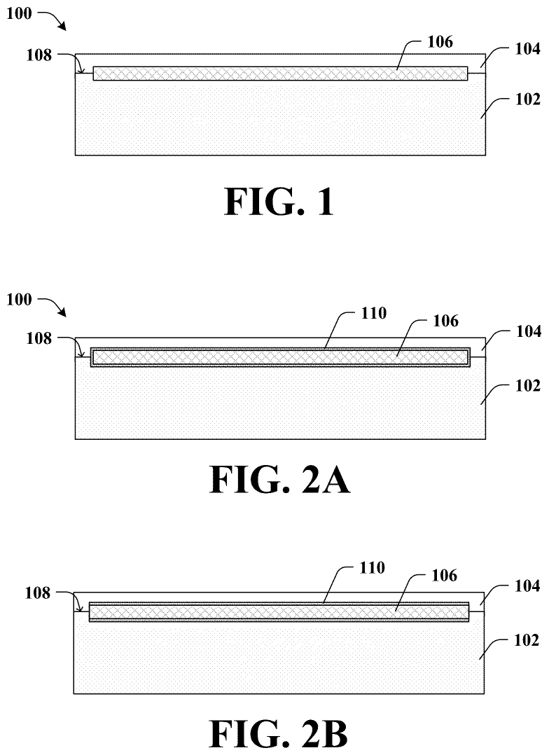

FIG. 1 illustrates a cross-sectional view of some embodiments of a thermal leveler blank 100. The thermal leveler blank 100 includes a first encapsulating layer 102 bonded to a second encapsulating layer 104. The thermal leveler blank 100 further includes a thermal spreader layer 106 arranged between the first and second encapsulating layers 102, 104. In some embodiments, the thermal spreader layer 106 is generally planar and is thinner than the first encapsulating layer 102. In some embodiments, the thermal spreader layer 106 is also thinner than the second encapsulating layer 104. At least the first encapsulating layer 102 has a thickness and is formed of a material configured to accommodate post-fabrication machining into the first encapsulating layer 102 as desired. In some embodiments, the second encapsulating layer 104 also has a thickness and is formed of a material configured to accommodate post-fabrication machining into the second encapsulating layer 104.

In some examples, the thermal spreader layer 106 has a width that is less than a width of the first encapsulating layer 102 and less than a width of the second encapsulating layer 104 such that the thermal spreader layer 106 is completely surrounded by the first and second encapsulating layers 102, 104. In some embodiments, the first encapsulating layer 102 contacts the second encapsulating layer 104 at a first bonding interface 108. In some embodiments, the first bonding interface 108 directly surrounds the outermost sidewalls of the thermal spreader layer 106 such that the first bonding interface 108 is arranged between a topmost surface and a bottommost surface of the thermal spreader layer 106.

In some embodiments, the thermal spreader layer 106 includes a material having a relatively high thermal conductivity and a higher thermal conductivity than materials of the first and second encapsulating layers 102, 104. In some embodiments, the thermal spreader layer 106 has the highest thermally conductive material of all components in the thermal leveler blank 100. The thermally conductive material of the thermal spreader layer 106 may be chosen for the desired application of the thermal leveler blank 100. In some embodiments, the thermal spreader layer 106 includes, for example, graphite material, aluminum nitride (AlN), aluminum, copper, molybdenum, diamond, a combination of two or more thereof, and the like. In some embodiments, where the thermal spreader layer 106 includes a graphite material, the graphite material may be pyrolytic graphite or thermal pyrolytic graphite. Thermal pyrolytic graphite may be used interchangeably with “highly oriented pyrolytic graphite” (“HOPG”), or compression annealed pyrolytic graphite (“CAPG”). Thermal pyrolytic graphite is extremely thermally conductive with an in-plane (a-b direction) thermal conductivity greater than 1000 W/m-K, while the thermal conductivity in the out-of-plane (z-direction) is in the range of 5 to 30 W/m-K. In one embodiment, thermal pyrolytic graphite has an in-plane thermal conductivity greater than 1,500 W/m-K.

Further, the thermal spreader layer 106 may include a thermal conductive material that has a higher in-plane thermal conductivity than the first and second encapsulating layers 102, 104; a favorable coefficient of thermal expansion in view of the first and second encapsulating layers 102, 104; and the capability to generate reliable or non-variable bonding between the encapsulating layers 102, 104 and the thermal spreader layer 106. In some embodiments, the coefficient of thermal expansion of the thermal spreader layer 106 is equal to or substantially the same as the coefficient of thermal expansion of the encapsulating layers 102, 104 to prevent separation of the layers during temperature changes. In other embodiments, the coefficient of thermal expansion of the thermal spread layer 106 is different than the coefficient of thermal expansion of the encapsulating layers 102, 104. In some embodiments, the thermal spreader layer 106 includes one or more layers of a highly thermally conductive material where the layers may be oriented vertically, horizontally, or at an angle depending on the application and desired heat distribution. It is understood that the aforementioned examples are not intended to be limiting and that thermal the thermal spreader layer 106 may be of a different material having a higher thermal conductivity relative to the thermal conductivity of the outer encapsulating layers 102, 104.

In some embodiments, the thermal spreader layer 106 is arranged to facilitate separate zones of heating or cooling, by introducing discrete thermal pyrolytic graphite and/or other thermally conductive materials. For example, the thermal spreader layer 106 may include structures, such as, but not limited to, tiles, air gaps, substrate ribs, vias, or other structural members in certain locations, or insertions of other different materials of low thermal conductivity. For example, thermal pyrolytic graphite tiles, structural members, gaps, other materials, etc., may be matched to heating or cooling structure zones for enhanced zone control as well as uniformity. Additionally, vias and/or structural webbing can be present in the thermal pyrolytic graphite and/or other thermally conductive material cavities of encapsulating layers 102, 104 to aid with structural strength.

In some embodiments, the first and second encapsulating layers 102, 104 are external layers of the thermal leveler blank 100. As will be described further herein, the first and/or second encapsulating layers 102, 104 may contact heaters, heater coils, cooling lines (e.g., gas, water, etc.) or some other thermal management devices and prevent direct contact between the thermal management devices and the thermal spreader layer 106. Further, it will be appreciated that in some other embodiments, the first and second encapsulating layers 102, 104 may be a single, monolithic encapsulant structure, where the thermal spreader layer 106 is embedded within the single, monolithic encapsulant structure. It will also be appreciated that in yet some other embodiments, the thermal leveler blank 100 may include more than two encapsulating layers 102, 104. For example, in such other embodiments, a third encapsulating layer (not shown) may be present between the first and second encapsulating layers 102, 104. In some other embodiments, an additional thermal ‘spreader layer (not shown) may be sandwiched between the third encapsulating layer and the first or second encapsulating layers 102, 104. In some other embodiments, the first and second encapsulating layers 102, 104 could themselves be constructed of a plurality of layers made through stack forging or additive manufacturing.

The first encapsulating layer 102 may include a same material or a different material than the second encapsulating layer 104. To promote bonding and prevent thermal expansion issues, the first encapsulating layer 102 is often the same as the second encapsulating layer 104. Outermost surfaces of the encapsulating layers 102, 104 may be generally planar to allow for post-processing of the thermal leveler blank 100. In some embodiments, the first and second encapsulating layers 102, 104 may include graphite, metal, semimetals, alloys, ceramics, or combinations thereof. For example, in some embodiments, the first and second encapsulating layers 102, 104 include titanium, nickel, chromium, copper, aluminum, 6061 aluminum, stainless steels, tungsten, molybdenum, iron, carbon steels, tin, silver, gold, beryllium, alloys or composites thereof, and oxides or nitrides thereof (e.g., aluminum nitride, aluminum oxide, etc.). Suitable examples of ceramic materials that may be used for the first and second encapsulating layers 102, 104 include metal carbides (e.g., silicon carbide), metal nitrides (e.g., silicon nitride, aluminum nitride), metal oxides (e.g. aluminum oxide), silicon, cermets (AlSiC) and the like. As will be discussed further herein, the first and second encapsulating layers 102, 104 may include a material suitable for the bonding technique used to bond the first and second encapsulating layers 102, 104 at the first bonding interface 108. Further, the first and second encapsulating layers 102, 104 may be a material that is not corrosive when exposed to chemicals present in processing chambers (e.g., etching gases, CVD reactants, etc.). In some such embodiments, the first and/or second encapsulating layers 102, 104 may include stainless steel, nickel alloys, or some other suitable anti-corrosive materials. Stainless steel and nickel alloys have lower thermal conductivities than other metals such as aluminum; thus, including a thermal spreader layer 106 in a thermal leveler blank 100 having stainless steel and/or nickel alloys may be particularly useful for temperature uniformity in higher temperature applications.

Further, in some embodiments, the first and second encapsulating layers 102, 104 may be a material commonly used in heater pedestals for semiconductor processing. In an embodiment, the encapsulating layers 102, 104 are formed from a material that matches the composition or material of a heater pedestal upon which the thermal leveler blank 100 may be used for processing. In an embodiment, each of the encapsulant layers 102, 104 may include one or more layers of a lower thermally conductive material compared to the thermal spreader layer 106. In an embodiment, the encapsulating layers 102, 104 may not be orientation dependent and may be provided in any orientation. Because of the presence of the thermal spreader layer 106, thermal fluctuations near the pedestal are reduced.

Turning additionally to FIG. 2, in some embodiments, the thermal leveler blank 100 further includes an interface layer 110 separating the thermal spreader layer 106 from the first and second encapsulating layers 102, 104. In some embodiments, the interface layer 110 surrounds upper, lower, and peripheral (or lateral) surfaces of the thermal spreader layer 106, as shown in FIG. 2A. In some other embodiments, the interface layer 110 may, for example, cover upper and lower surfaces of the thermal spreader layer 106, while the peripheral (or lateral) surfaces of the thermal spreader layer 106 directly contact the first and/or second encapsulating layers 102, 104 as shown in FIG. 2B. In some embodiments, the interface layer 110 may be oriented in-plane (e.g., planar). The interface layer 110 may be a continuous, a non-continuous, or a patterned layer. The interface layer 110 may not be present at the first bonding interface 108 such that the interface layer 110 does not interfere with the bonding between the first and second encapsulating layers 102, 104. In some other embodiments, the interface layer 110 may assist with bonding at the first bonding interface 108. In some such other embodiments, the interface layer 110 is arranged between the first and second encapsulating layers 102, 104 at the first bonding interface 108.

The interface layer 110 may assist with bonding, with thermal spreading, with diffusion prevention, or some other function. In some embodiments, the interface layer 110 includes several sublayers having the same or different interface materials. In some embodiments, the interface layer 110 includes one or more materials suitable for its particular function and in view of the materials of the first encapsulating layer 102, the thermal spreader layer 106, and the second encapsulating layer 104. For example, when the thermal spreader layer 106 includes carbon (such as thermal pyrolytic graphite), the interface layer 110 may include a carbide-forming metal or material to act as a carbon diffusion barrier between the thermal spreader layer 106 and the encapsulating layers 102, 104. For example, when the encapsulating layers 102, 104 are metal alloys containing iron and chromium, carbon diffusion between the carbon-containing thermal spreader layer 106 and the iron and chromium containing encapsulating layers 102, 104 should be reduced to maintain their structure and thus, corrosion resistance, of the encapsulating layers 102, 104. In some embodiments, for example, the first and second encapsulating layers 102, 104 may include stainless steel and/or nickel alloys, which may experience carbon diffusion, but which also are resistant to degradation by chemicals used in manufacturing processes such as fluorine used in in-situ cleaning processes. In some embodiments, the interface layer 110 includes, for example, titanium, zirconium, chromium, hafnium, aluminum, tantalum, nickel, iron, silicon, molybdenum, a carbide, transition metals, or a combination of two or more thereof. The interface layer 110 may have a lower thermal conductivity than the thermal spreader layer 106. In some embodiments, the interface layer 110 has a same or substantially similar thermal conductivity as the first and second encapsulating layers 102, 104. In some other embodiments, the interface layer 110 has a higher thermal conductivity than the first and second encapsulating layers 102, 104.

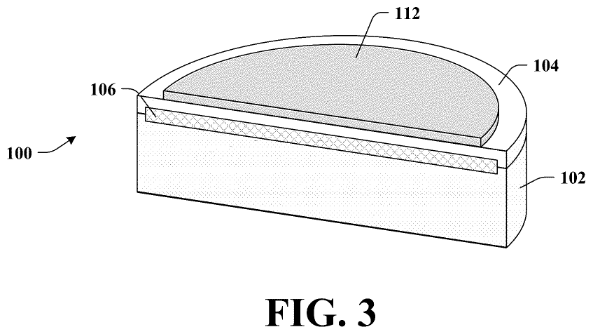

Turning additionally to FIG. 3, a partial perspective view of some embodiments of the thermal leveler blank 100 is illustrated. In some embodiments, the thermal leveler blank 100 is configured to support a wafer 112 for processing (e.g., deposition processes, etching processes, etc.). The thermal leveler blank 100 may have a cylindrical, plate-like shape to support the wafer 112. In some embodiments, the thermal leveler blank 100 has a greater width than the wafer 112. Similarly, the thermal spreader layer 106 may have a greater width than the wafer 112. This way, the entirety of the wafer 112 directly overlies the thermal spreader layer 106 to improve the temperature uniformity of the wafer 112 as distributed by, in part, the thermal spreader layer 106.

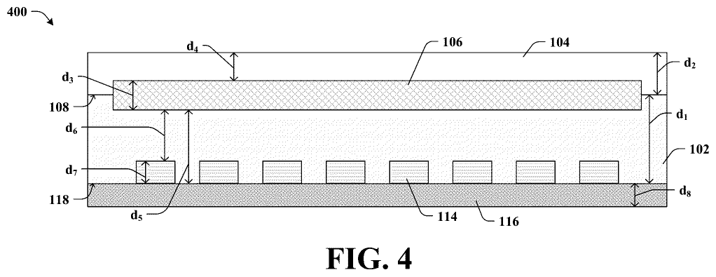

FIG. 4 illustrates an enlarged cross-sectional view of some embodiments of a thermal leveler 400, which may be formed from the thermal leveler blank 100 described in FIGS. 1-3, for example.

As shown in FIG. 4, the first encapsulating layer 102 may be machined to accommodate a thermal control structure 114, such as, for example, a heating coil, a cooling structure (e.g., gas lines, water lines) or some other thermal management device. The thermal control structure 114 may have a bottommost surface that is substantially coplanar with a bottommost surface of the first encapsulating layer 102. In other embodiments, thermal control structure 114 may have a bottommost surface that is above or below the bottommost surface of the first encapsulating layer 102. It will be appreciated that the first encapsulating layer 102 may be machined in a variety of ways to accommodate a particular thermal management device. In some embodiments, the first and second encapsulating layers 102, 104, the thermal spreader layer 106, and the thermal control structure 114 together reduce temperature variation in the thermal leveler 400. In some embodiments, the combination of layers in the thermal leveler 400 eliminates the need for complex temperature uniformity techniques such as adding additional heating zones, pumping zones, gas flow patterns, and the like. In other embodiments, these additional temperature uniformity techniques may be used in addition to the provided thermal leveler 400.

To enclose the thermal control structure 114 and provide structural support, a third encapsulating layer 116 may be bonded to the first encapsulating layer 102 such that the thermal control structure 114 is between the first encapsulating layer 102 and the third encapsulating layer 116. For instance, in some embodiments, the thermal control structure 114 is sandwiched between the first encapsulating layer 102 and the third encapsulating layer 116. The third encapsulating layer 116 may include the same or different material as the first encapsulating layer 102. The third encapsulating layer 116 is bonded to the first encapsulating layer 102 at a second bonding interface 118. In some embodiments, the method of bonding at the first bonding interface 108 is different than the method of bonding at the second bonding interface 118. For example, the first and second encapsulating layers 102, 104 may be bonded at the first bonding interface 108 at extremely high temperatures using diffusion bonding, whereas the first and third encapsulating layers 102, 116 may be bonded at the second bonding interface 118 at lower temperatures and/or with more localized heating, such as through soldering, welding, or brazing, to form the second bonding interface 118 without disrupting the bond at the first bonding interface 108. In some other embodiments, to access the thermal control structure 114, the first encapsulating layer 102 may be removably coupled to the third encapsulating layer 116 at the second bonding interface. For example, the first and second encapsulating layers 102, 116 may be removably coupled through threading, a clamp, a clicking structure, or some other removable connection. The thermal leveler 400 may be configured to be directly integrated into a traditional pedestal heater used in semiconductor processing. The thermal leveler 400 may be configured to be machined and “become” the heater or cooling device when the thermal control structure 114 is added. Since the thermal leveler 400 may first be provided as a blank (e.g., 100 of FIG. 1) having thicker outer layers, the thermal leveler 400 can be fabricated with surface features (heating or cooling) to accommodate various heater structures and thermal management systems such as a heater, cold plate, or other device desiring thermal uniformity or heat spreading.

The first encapsulating layer 102 has a thickness equal to a first distance d₁; the second encapsulating layer 104 has a thickness equal to a second distance d₂; and the thermal spreader layer 106 has a thickness equal to a third distance d₃. For the purposes of this discussion of dimensions of the layers in the thermal leveler 400 of FIG. 4, it will be assumed that the thickness (d₁) of the first encapsulating layer 102 and the thickness (d₂) of the second encapsulating layer 104 are the same as the respective thicknesses of the first and second encapsulating layers 102, 104 of the thermal leveler blank (e.g., 100 of FIG. 1) used to form the thermal leveler 400 of FIG. 4. It will be appreciated though, that the thicknesses of the encapsulating layers 102, 104 may be changed when the thermal leveler blank (e.g., 100 of FIG. 1) is post-processed into the thermal leveler 400 of FIG. 4.

Further, it will be appreciated that when discussing dimensions in FIG. 4, if interface layers (e.g., 110 of FIG. 2) are arranged between the thermal spreader layer 106 and the encapsulating layers 102, 104, the thickness of the interface layers are very small but also are included in the dimensions of the encapsulating layers 102, 104. For example, a topmost surface of the second encapsulating layer 104 may be spaced apart from a topmost surface of the thermal spreader layer 106 by a fourth distance d₄. If an interface layer (e.g., 110 of FIG. 2) was arranged between the second encapsulating layer 104 and the thermal spreader layer 106, then the interface layer (e.g., 110 of FIG. 2) would be included in the fourth distance d₄ but not included in the third distance d₃, which is the thickness of the thermal spreader layer 106. A bottommost surface of the thermal spreader layer 106 may be spaced apart from the bottommost surface of the second encapsulating layer 104 by a fifth distance d₅. The bottommost surface of the thermal spreader layer 106 may be spaced apart from a topmost surface of the thermal control structure 114 by a sixth distance d₆. The thermal control structure 114 may have a height equal to a seventh distance d₇. In some embodiments, when the thermal control structure 114 has a bottommost surface coplanar with the bottommost surface of the first encapsulating layer 102, the fifth distance d₅ is equal to a sum of the sixth distance de and the seventh distance d₇. The third encapsulating layer 116 may have a thickness equal to an eighth distance d₈.

In some embodiments, at least one of the first or second distances d₁, d₂ is greater than the third distance d₃. The first distance d₁ is often thicker than the second distance d₂ to accommodate for post-processing. In some other embodiments, such as if the first and second encapsulating layers 102, 104 are both post-processed, the first and second distances d₁, d₂ may have a substantially same thickness or may be different. In some embodiments, each of the first and second distances d₁, d₂ (i.e., the thicknesses of the first and second encapsulating layers 102, 104) may preferably be in a range of between, for example, approximately 0.5 millimeters and approximately 50 millimeters, more preferably in a range of between, for example, approximately 1 millimeter and approximately 20 millimeters, even more preferably in a range of between approximately 1 millimeter and approximately 10 millimeters, or yet even more preferably in a range of between approximately 4.5 millimeters and approximately 5 millimeters. In some embodiments, the sixth distance do, which is the distance between the thermal control structure 114 and the thermal spreader layer 106, may preferably be in a range of between, for example, approximately 1 millimeter and approximately 20 millimeters, more preferably in a range of between approximately 1 millimeter and approximately 10 millimeters, or even more preferably in a range of between approximately 4.5 millimeters and approximately 5 millimeters.

In some embodiments, the third distance d₃ (i.e., the thickness of the thermal spreader layer 106) may preferably be in a range of between, for example, approximately 0.25 mm and approximately 25 mm, more preferably in a range between approximately 0.50 mm and approximately 2.3 mm, and even more preferably in a range of between approximately 1.5 mm and approximately 2.0 mm. The thickness (d₃) of the thermal spreader layer 106 may depend on the overall desired thermal leveler dimensions, the materials of the thermal leveler 400, the cost of the product, and/or the amount of uniform thermal distribution needed for an application. The thickness (d₃) of the thermal spreader layer 106 is also dependent on the thicknesses (d₁, d₂) of the first and second encapsulating layers 102, 104 and the placement of the thermal control structure 114 (e.g., the sixth distance d₆). In some embodiments, a ratio of the fourth distance d₄ to the third distance d₃ is between about 0.5 and about 4, or more preferably between about 1.5 and 3. When the ratio of the fourth distance d₄ and the third distance d₃ is smaller, then temperature uniformity on an object (e.g., a wafer) resting on the second encapsulating layer 104 may be reduced. In some embodiments, the temperature difference divided by maximum temperature across a topmost surface of the second encapsulating layer 104 may be between about +/−0.5 percent and about +/−4 percent when the ratio d₄ to d₃ is between about 0.5 and about 4. When the ratio of d₄ to d₃ is between about 1.5 and about 2, for example, the temperature difference across a topmost surface of the second encapsulating layer 104 may be between about 5 degrees Celsius and 6 degrees Celsius. In some instances, when the layers 102, 104, 106 are thicker, the temperature uniformity of the thermal leveler 400 may be improved, but the average temperature of the thermal leveler 400 may be reduced, which may not be desired for heating applications.

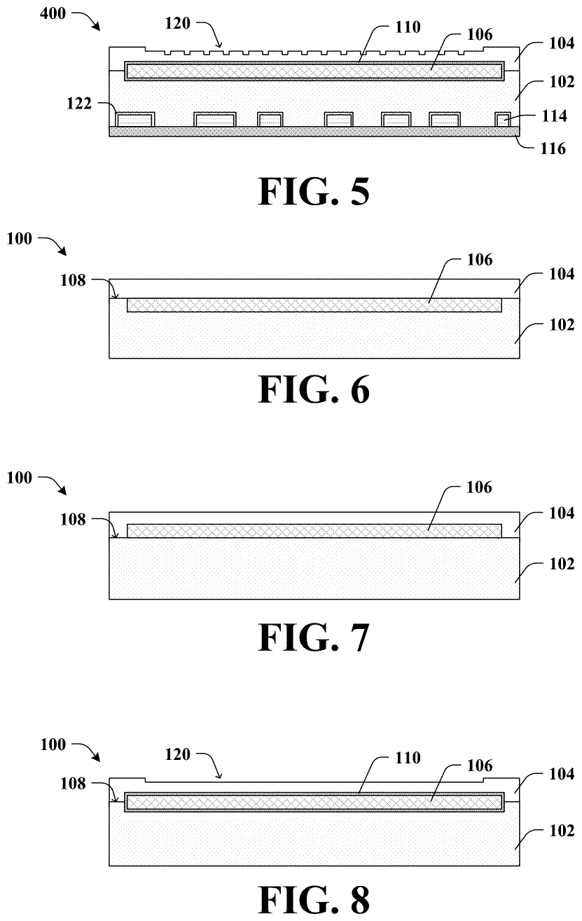

Turning additionally to FIG. 5, in some embodiments, the second encapsulating layer 104 may also be machined. For example, in some embodiments, the second encapsulating layer 104 includes a pattern 120 to accommodate one or more thermal management devices (backside gas channels, mesas, etc.). In some other embodiments, the pattern 120 on the topmost surface of the second encapsulating layer 104 is configured to accommodate one or more wafers (e.g., 112 of FIG. 3) to be held by the thermal leveler 400. In some embodiments, a through hole (ex. lift pin) can be machined through the first (102) and second (104) encapsulating layers. Thus, in some embodiments, post-processing of a thermal leveler blank (e.g., 100 of FIG. 2) can be performed during a different manufacturing step and result in a thermal leveler 400 with the integration of a proprietary customer design on the topmost surface of the second encapsulating layer 104 (ex. cutouts, gas channels, lift pins, mesas, chucking clamps, etc.) as well as a proprietary design on the bottommost surface of the first encapsulating layer 102. (ex. channels for heating coils, cooling channels, etc.) to enable high temperature uniformity and/or zone control of the thermal leveler blank 100. For example, in some embodiments, higher temperature zones may be desired at a periphery of the thermal leveler 400; in some such embodiments, the thermal spreader layer 106 and/or the thermal control structure 114 are designed to provide increased temperature towards the periphery. Further, in some embodiments, additional interface layers 122 may be arranged between the thermal control structure 114 and the first encapsulating layer 102.

Turning now to FIGS. 6, 7, 8, and 9, some alternative embodiments of a thermal leveler blank 100 are illustrated.

As shown in FIG. 6, in some embodiments, the thermal spreader layer 106 is arranged within a recess of the first encapsulating layer 102, while the second encapsulating layer 104 is a substantially flat plate having a uniform thickness and substantially planar bottommost surface. In some such embodiments, the first bonding interface 108 may be substantially coplanar with bottom surface of the second encapsulating layer 104 and with topmost surfaces of the thermal spreader layer 106 (or interface layers 110 of FIG. 2, if present) and the first encapsulating layer 102.

As shown in FIG. 7, the thermal spreader layer 106 is arranged within a recess of the second encapsulating layer 104, while the first encapsulating layer 102 is a substantially flat plate having a uniform thickness and substantially planar bottommost surface. In some such embodiments, the thermal spreader layer 106 rests on the topmost surface of the first encapsulating layer 102. In some such embodiments, the first bonding interface 108 may be substantially coplanar with a topmost surface of the first encapsulating layer 102 and with bottommost surfaces of the thermal spreader layer 106 (or interface layers 110 of FIG. 2, if present) and the second encapsulating layer 104.

As shown in FIG. 8, in some embodiments, the thermal leveler blank 100 may include a pattern 120 on the topmost surface of the second encapsulating layer 104. In some such embodiments, the pattern 120 may be a recess or pocket configured to accommodate a wafer (e.g., 112 of FIG. 3). The thermal leveler blank 100 may be sold with this pattern 120 on the second encapsulating layer 104, while the first encapsulating layer 102 may be sold as pattern-less; in some such embodiments, the first encapsulating layer 102 may then be machined by a customer to achieve a desired, proprietary pattern and thermal management system on the backside of the thermal leveler blank 100. The thermal leveler blank 100 includes sufficient material on the upper and lower surfaces such that the application (heating or cooling) is not in direct contact with the thermal spreader layer 106. Thus, even with the pattern 120 on the second encapsulating layer 104, the second encapsulating layer 104 still separates the thermal spreader layer 106 from any wafers (e.g., 112) received on the second encapsulating layer 104.

The thermal leveler blank 100 is illustrated with an interface layer 110 in FIG. 8. It will be appreciated that the interface layer 110 may also be present in the embodiments illustrated in FIGS. 6 and 7.

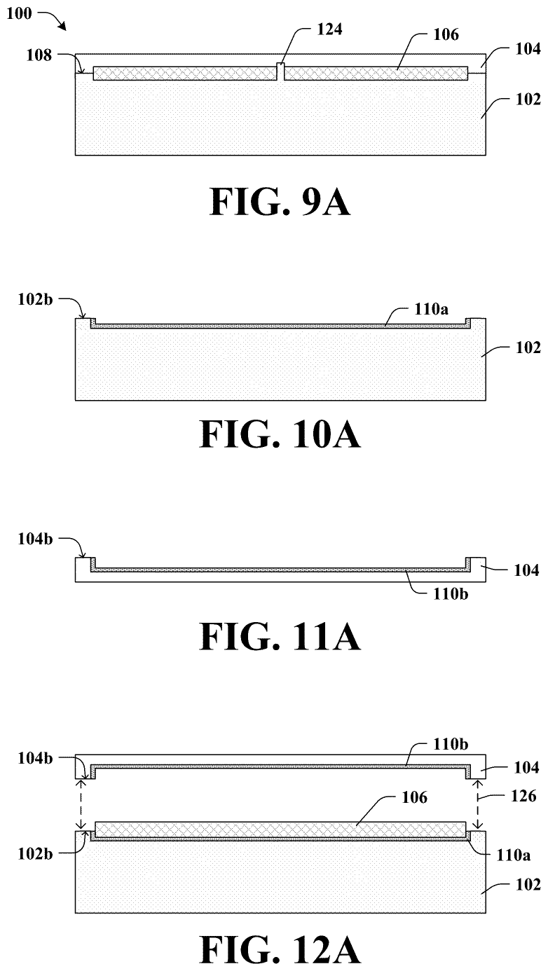

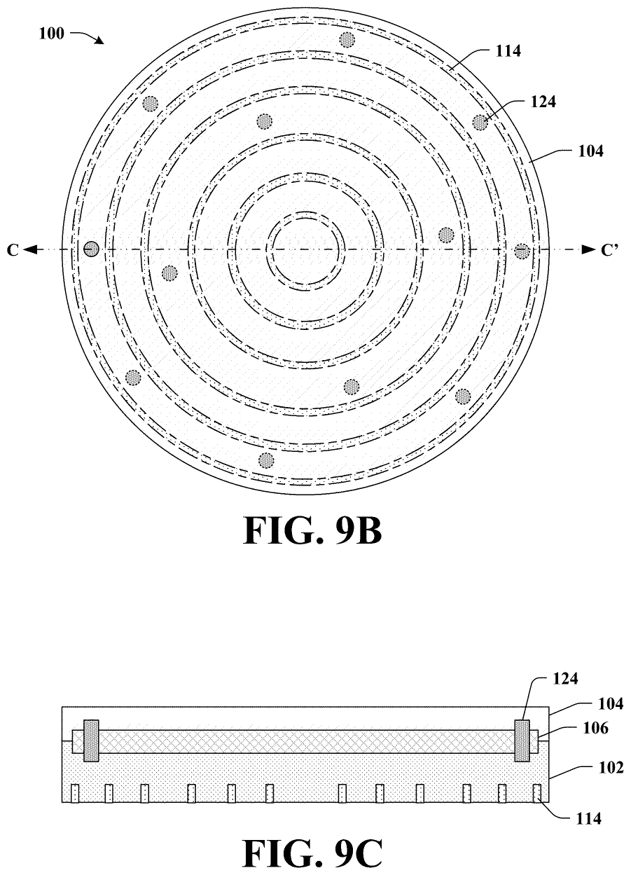

As shown in FIG. 9A, in some embodiments, the thermal leveler blank 100 may further include a support via 124. The support via 124 may extend through a portion of the thermal spreader layer 106. In some embodiments, as shown in FIG. 9, the support via 124 is a protrusion from the first encapsulating layer 102 and is continuously formed with the first encapsulating layer 102. In some other embodiments, the support via 124 is a protrusion from the second encapsulating layer 104 or is a separate component arranged between the first and second encapsulating layers 102, 104. The support via 124 is bonded to the second encapsulating layer 104. In some embodiments, the same bonding technique used to form the first bonding interface 108 is also used to bond the support via 124 to first and/or second encapsulating layers 102, 104. The support via 124 may provide structural support to the thermal leveler blank 100 and/or may assist with thermal distribution throughout the thermal leveler blank 100. In some embodiments, several support vias 124 may be arranged throughout the thermal leveler blank 100. Further, in some embodiments, interface layers (e.g., 110 of FIG. 2) may be arranged directly between the support via 124 and the thermal spreader layer 106 to assist with diffusion prevention, bonding, thermal dissipation, or the like. In some embodiments, when the thermal leveler blank 100 is machined to include a thermal control structure (e.g., 114 of FIG. 4), the support via 124, if present, is designed to not directly overlie portions of the thermal control structure to improve temperature uniformity of the thermal leveler. Thus, in some such embodiments, the thermal control structure (e.g., 114 of FIG. 4) may be designed to directly underlie the thermal spreader layer 106.

FIG. 9B illustrates a top view of some embodiments of the distribution of the support vias 124 throughout the thermal leveler 100. In some embodiments, the thermal leveler 100 includes a thermal control structure 114 which may include, for example, a heating coil, a cooling structure (e.g., gas lines, water lines), or some other thermal management device. The thermal control structure 114 may be arranged on or integrated with one of the first and/or second encapsulating layers 102, 104. In some embodiments, the thermal control structure 114 has a pattern to distribute heat and/or cooling air or water through the thermal leveler 100. In FIG. 9B, the thermal control structure 114 and the support vias 124 are outlined with hashed lines; it will be appreciated that the thermal control structure 114 and the support vias 124 are covered by, for example, the second encapsulating layer 104 from the top view of FIG. 9B. In some embodiments, when the thermal leveler 100 is manufactured to include the thermal control structure 114, the support via(s) 124, if present, is preferably designed to not directly overlie portions of the thermal control structure 114 to improve temperature uniformity of the thermal leveler 100. When the support vias 124 do not directly overlie portions of the thermal control structure 114, the temperature uniformity of the thermal leveler 100 is improved. In some other embodiments, due to design constraints and/or due to varying heating zone specifications, one or more of the support vias 124 may be partially or fully aligned/overlapped with the thermal control structure 114 in the vertical direction.

FIG. 9C illustrates some embodiments of a cross-sectional view of the thermal leveler 100 corresponding to cross-section line CC' of FIG. 9B. Because the support vias 124 do not directly align or overlap with the thermal control structure 114 in the vertical direction, the thermal control structure 114 may directly align or overlap with the thermal spreader layer 106 in the vertical direction. In other embodiments where there is full or partial overlap of the support vias 124 and the thermal control structure 114, no part or only some part of the thermal control structure 114 directly aligns/overlaps the thermal spreader layer 106 in the vertical direction.

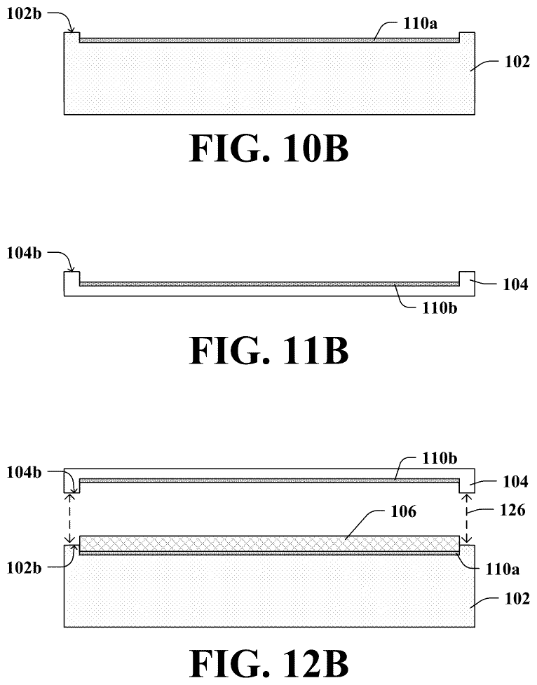

FIGS. 10, 11, 12, 13, 14, 15A, 15B, 16, and 17 illustrate some embodiments of a method of forming the thermal leveler blank and thermal leveler as described above. It will be appreciated that the method is exemplary and that the various steps may be performed in a different order and/or using different techniques.

FIGS. 10 and 11 will be described together. As shown in FIG. 10, the first encapsulating layer 102 is provided and a first interface layer 110a is formed on an upper surface of the first encapsulating layer 104. In FIG. 10A, the first interface layer 110a is formed such that the first interface layer 110a partially covers peripheral or lateral surfaces of the thermal spreader layer 106 (see FIGS. 2A and 12A). In FIG. 10B, the first interface layer 110a is formed such that the first interface layer 110a covers a top surface of the thermal spreader layer 106 (see FIGS. 2B and 12B). As shown in FIG. 11, the second encapsulating layer 104 is provided and a second interface layer 110b is formed on an upper surface of the second encapsulating layer 104. In FIG. 11A, the second interface layer 110b is formed such that the second interface layer 110b partially covers peripheral or lateral surfaces of the thermal spreader layer 106 (see FIGS. 2A and 12A). In FIG. 11B, the second interface layer 110b is formed such that the second interface layer 110b covers a bottom surface of the thermal spreader layer 106 (see FIGS. 2B and 12B). In some other embodiments, the first and/or second interface layers 110a, 110b may be omitted. In some embodiments, the first and/or second encapsulating layers 102, 104 may include a metal suitable for post-processing methods (including but not limited to iron(s), carbon steels, stainless steels, nickel and nickel alloys, titanium, molybdenum, tungsten, copper, aluminum, or combinations or alloys of the same, and composites including molybdenum-copper). These metal encapsulating layers 102, 104 could be wrought, cast, or manufactured through additive manufacturing. If additively manufactured, the encapsulating layers 102, 104 could include integrated as-printed features such as, but not limited to, heating and/or cooling channels. The wrought or additive manufactured substrates would have pockets (either machined or as-printed) to accommodate the thermal spreader layer 106 as will be discussed in FIG. 12. In some embodiment, the encapsulating layers 102, 104 could be made up of multiple layers of material bonded together, with a designed recess to accommodate the thermal spreader layer (106). In some other embodiments, the first and second encapsulating layers 102, 104 may include a ceramic material, a composite material, or combinations thereof.

The interface layers 110a, 110b may include a carbide-forming metal or material that may also act to control carbon diffusion. The interface layers 110a, 110b may be formed on the encapsulating layers 102, 104 by foil, plating, thermal spray coating, sputter coating, or other deposition processes (e.g., CVD, PVD, PE-CVD, ALD, etc.). for example. In some other embodiments, the interface layers 110a, 110b are formed directly on the encapsulating layers 102, 102; while in some other embodiments, the interface layers 110a, 110b are formed on the thermal spreader layer (106 of FIG. 12). In some embodiments, the interface layers 110a, 110b have a thickness between approximately 1 micron and 50 microns, approximately 5 microns and 10 microns, approximately 5 microns to 25 microns, approximately 1 and 750 microns, between approximately 2 and 500 microns, or greater than 1 microns, for example. In one example, the thickness is between approximately 25 and 50 microns. When the thickness of the interface layers 110a, 110b is between, for example, approximately 5 microns and 50 microns, the interface layers 110a, 110b may enable a strong metal-to-metal bond and/or prevent carbon diffusion from the thermal spreader layer 106 into the encapsulating layers 102, 104 without significantly lowering the mechanical strength of the bond.

The carbon diffusion into the interface layers 110a, 110b often stops between about 1 and 15 microns. In some such embodiments, the carbon diffusion barrier effect of the interface layers 110a does not change once the thickness is greater than about 20 to 50 microns. For example, when the interface layers 110a, 110b include chromium, the interface layers 110a, 110b have a thickness of about 10 to 60 microns; and when the interface layers 110a, 110b include molybdenum, the interface layers 110a, 110b have a thickness of about 10 to 60 microns. In some embodiments, when the interface layers 110a, 110b each include chromium having a thickness of between about 25 and 40 microns, carbon diffusion is blocked, 110b are not fully consumed.

In some embodiments, a bonding surface 102b of the first encapsulating layer 102 is free of the first interface layer 110a, and a bonding surface 104b of the second encapsulating layer 104 is free of the second interface layer 110b. In some such embodiments, the bonding surfaces 102b, 104b may be masked during the formation of the interface layers 110a, 110b, and then the mask may be removed from the bonding surfaces 102b, 104b. In some other embodiments, the interface layers 110a, 110b may be formed continuously over the encapsulating layers 102, 104, and then removed from the bonding surfaces 102b, 104b. Removal methods include CMP, etching, or some other suitable technique. In other embodiments, the interface layers 110a, 110b be cut to a desired shape from a metal foil. In other embodiments, the interface layers 110a, 110b may remain on the bonding surfaces 102b, 104b and aid with future bonding at that interface.

As shown in FIGS. 12, the first and second encapsulating layers 102, 104 may be aligned such that the first interface layer 110a faces the second interface layer 110b. FIG. 12A depicts the interface layer 110 formed to cover a top surface, a bottom surface, and peripheral surfaces of the thermal spreader layer 106. FIG. 12B depicts the interface layer formed to cover the top surface and the bottom surface of the thermal spread layer 106, but not the peripheral or lateral surfaces. The thermal spreader layer 106 is arranged between the first and second encapsulating layers 102, 104. The thermal spreader layer 106 is sized to fit within the inner space between the first and second encapsulating layers 102, 104. The bonding surface 102b of the first encapsulating layer 102 is then aligned with and bonded to the bonding surface 104b of the second encapsulating layer 104 through a bonding process 126.

In some embodiments, the bonding process 126 may be performed at high or elevated temperature. For example, in some embodiments, the bonding process 126 is performed at a temperature greater than or equal to approximately 450 degrees Celsius, or in some other embodiments, greater than or equal to approximately 1000 degrees Celsius. When such high temperatures are used, the thermal spreader layer 106 includes a material that maintains its integrity when exposed to such high temperatures. In an embodiment, the bonding method for making the thermal leveler blank 100 may include diffusion bonding, for example, but not limited to, vacuum hot pressing (which is uniaxial applied force) and hot isostatic pressing (which applies force in all direction using a gas), wherein the encapsulating layers 102, 104 are bonded to one another through high temperature and pressure. In some embodiments, the pressure is greater than, for example, 5 ksi. Such high or elevated temperatures used with diffusion bonding may prevent the introduction of semiconductor “poison” elements and enable the integration of heating or cooling applications during post-processing methods with brazing. For example, the high temperature utilized for the bonding process 126 to form the thermal leveler blank 100 is greater than temperatures used in post-processing of the thermal leveler blank 100. This way, the post-processing temperatures will not compromise the diffusion bond at the first bonding interface 108 in the thermal leveler blank 100. In an embodiment, high temperature brazing, welding, or additive manufacturing may also be used for forming the thermal leveler blank 100.

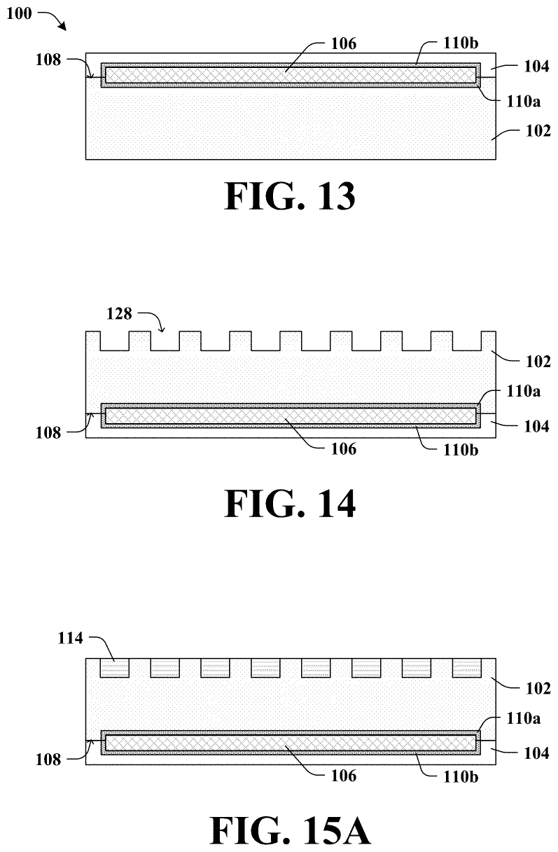

As shown in FIG. 13, the thermal leveler blank 100 is formed after the bonding process 126 is performed where the first and second encapsulating layers 102, 104 are bonded together at the first bonding interface 108. In some embodiments, the bonding process 126 permanently couples the first encapsulating layer 102 to the second encapsulating layer 104. “Permanently coupled” means that significant effort, such as cutting, extreme heating, or the like, would be required to separate the first encapsulating layer 102 from the second encapsulating layer 104. Additionally, some diffusion between the encapsulating layers 102, 104, the interface layers 110a, 110b, and the thermal spreader layer 106 may occur during the diffusion bonding process. The thermal leveler blank 100 may be further machined, as will be discussed in FIGS. 14, 15A, 15B, 16, and 17 to form a thermal leveler.

As shown in FIG. 14, the backside of the first encapsulating layer 102 may be machined to form a backside pattern 128 on the first encapsulating layer 102. The thickness of the first encapsulating layer 102 is great enough such that the backside pattern 128 does not expose the thermal spreader layer 106. Further, the first bonding interface 108 is strong enough such that the first bonding interface 108 remains strongly and permanently connected during the machining of the backside pattern 128. It will be appreciated that the backside pattern 128 is merely exemplary and other pattern designs may be used based on the thermal management device to be accommodated on the backside of the first encapsulating layer 102.

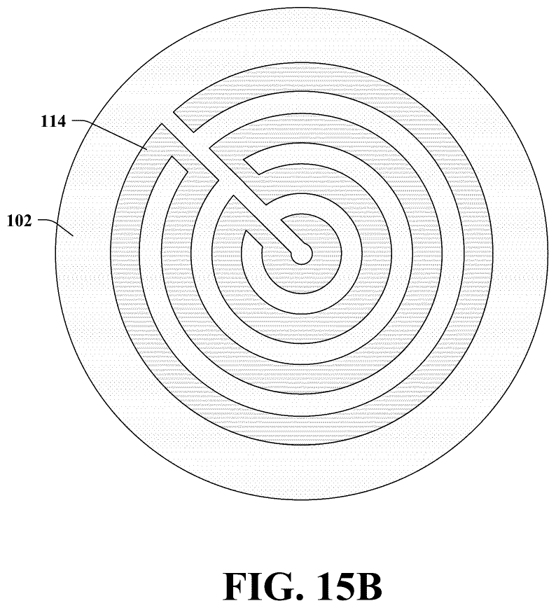

As shown in FIG. 15A, a thermal control structure 114 is placed in the backside pattern 128 of the first encapsulating layer. In some embodiments, the thermal control structure 114 rests within the backside pattern 128, whereas in other embodiments, an adhesive layer or bonding process may be used to secure the thermal control structure 114 within the backside pattern 128. Additionally, as discussed in FIG. 5, for example, the thermal control structure 114 or other suitable thermal management device (e.g., heater, cooling gas, cooling material, etc.) may include several layers.

FIG. 15B presents a top view of the thermal control structure 114 recessed within the first encapsulating layer 102. In some embodiments, the thermal control structure 114 includes a heating coil or cooling paths, for example.

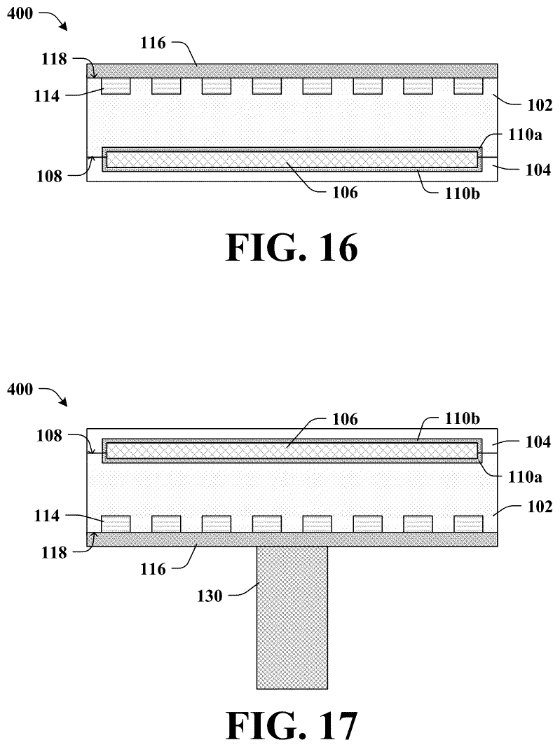

As shown in FIG. 16, a third encapsulating layer 116 may be coupled to the first encapsulating layer 102 to enclose and protect the thermal control structure 114 and form the thermal leveler 400 ready for use in various applications such as semiconductor processing. The third encapsulating layer 116 may be bonded to the first encapsulating layer 104. In some embodiments, the third encapsulating layer 116 is permanently bonded to the first encapsulating layer 104 using a bonding technique such as, for example, soldering, brazing, welding, or some other suitable bonding technique. The bonding technique used to bond the first encapsulating layer 102 with the third encapsulating layer 104 may be different than the bonding technique used to bond the first encapsulating layer 102 with the second encapsulating layer 104. For example, the bonding technique used to bond the first encapsulating layer 102 with the third encapsulating layer 116 may be performed at lower temperatures and/or with more localized heating at the second bonding interface 118 to avoid disrupting the bond at the first bonding interface 108. In other embodiments, the third encapsulating layer 116 may be removable coupled to the first encapsulating layer 102 such that the thermal control structure 114 can be accessed as needed without substantial effort such as cutting, extreme heat, or the like.

In some other embodiments, the thermal control structure 114 may be coupled to the third encapsulating layer 116 such that the thermal control structure 114 and the third encapsulating layer 116 are placed in the machined area of the first encapsulating layer 102 simultaneously.

It will be appreciated that the various interfaces between the thermal spreader layer 106, the interface layers 110a, 110b, the encapsulating layers 102, 104, 116, and the thermal control structure 114 are configured to provide a thermal leveler 400 having enhanced thermal management control, and/or reduced undesirable diffusion between the aforementioned layers, and/or enhanced bonding strength of materials and layers, and/or comparable thermal expansion coefficient (CTE) between the materials and layers. In some other embodiments, the second encapsulating layer 104 may also be patterned (e.g., FIG. 5) to provide additional functions or thermal management effects in the thermal leveler 400. Patterning techniques used for the second encapsulating layer 104 may be the same as or similar to the patterning techniques used for the first encapsulating layer 102.

As shown in FIG. 17, in some embodiments, the thermal leveler 400 further includes a pedestal 130. In some embodiments, the pedestal 130 is integrated with and is the same part as the third encapsulating layer 116. In some other embodiments the pedestal 130 is a separate part that is coupled to the third encapsulating layer 116. The thermal leveler 400 may be implemented into a processing chamber, receive a wafer for processing, and be able to withstand the various temperature, pressure, and humidity conditions used during the wafer processing while also providing excellent thermal distribution directed towards the wafer during processing.

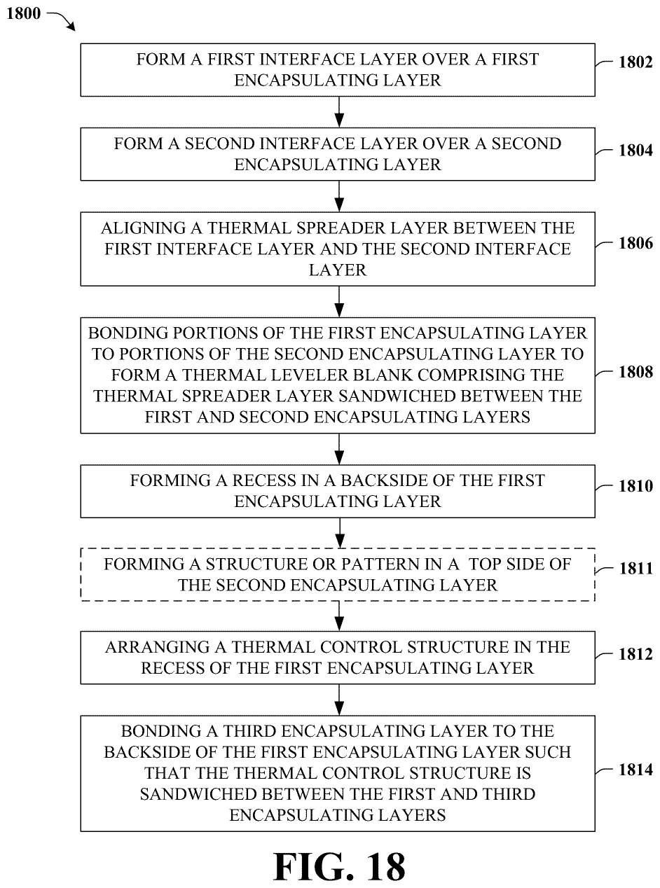

FIG. 18 provides a flow chart 1800 that shows the steps of some embodiments of the methods described above.

At step 1802, a first interface layer is formed over a first encapsulating layer.

At step 1804, a second interface layer is formed over a second encapsulating layer.

At step 1806, a thermal spreader layer is aligned between the first interface layer and the second interface layer.

At step 1808, portions of the first encapsulating layer are bonded to portions of the second encapsulating layer to form a thermal leveler blank comprising the thermal spreader layer sandwiched between the first and second encapsulating layers.

At step 1810, a recess is formed in a backside of the first encapsulating layer.

At step 1812, a thermal structure is arranged in the recess of the first encapsulating layer.

At step 1814, a third encapsulating layer is bonded to the backside of the first encapsulating layer such that the thermal structure is sandwiched between the first and third encapsulating layers.

Thus, the described thermal leveler and methods of making thereof may achieve one or more (or all) of the following: enable a high degree of design freedom; provide isolation of the heat spreader layer and bonding to its encapsulating material from a heating or cooling structure; and enable the use of custom cutouts, backside gas channels, custom chuck zones, etc. on the same or opposite surface as the heating or cooling structure. For example, in optional step 1811, such channels, structures, or patterns may be formed on a top surface of the second encapsulating layer (see, e.g., FIG. 5).

The aforementioned systems, components, (e.g., thermal leveler blanks, thermal management devices, among others), and the like have been described with respect to interaction between several components and/or elements. It should be appreciated that such devices and elements can include those elements or sub-elements specified therein, some of the specified elements or sub-elements, and/or additional elements. Further yet, one or more elements and/or sub-elements may be combined into a single component to provide aggregate functionality. The elements may also interact with one or more other elements not specifically described herein.

While the embodiments discussed herein have been related to the apparatus, systems and methods discussed above, these embodiments are intended to be exemplary and are not intended to limit the applicability of these embodiments to only those discussions set forth herein.

The above examples are merely illustrative of several possible embodiments of various aspects of the present invention, wherein equivalent alterations and/or modifications will occur to others skilled in the art upon reading and understanding this specification and the annexed drawings. In particular regard to the various functions performed by the above described components (assemblies, devices, systems, circuits, and the like), the terms (including a reference to a “means”) used to describe such components are intended to correspond, unless otherwise indicated, to any component, such as hardware, software, or combinations thereof, which performs the specified function of the described component (e.g., that is functionally equivalent), even though not structurally equivalent to the disclosed structure which performs the function in the illustrated implementations of the invention. In addition, although a particular feature of the invention may have been disclosed with respect to only one of several implementations, such feature may be combined with one or more other features of the other implementations as may be desired and advantageous for any given or particular application. Also, to the extent that the terms “including”, “includes”, “having”, “has”, “with”, or variants thereof are used in the detailed description and/or in the claims, such terms are intended to be inclusive in a manner similar to the term “comprising.”

This written description uses examples to disclose the invention, including the best mode, and also to enable one of ordinary skill in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that are not different from the literal language of the claims, or if they include equivalent structural elements with insubstantial differences from the literal language of the claims.

In the specification and claims, reference will be made to a number of terms that have the following meanings. The singular forms “a”, “an” and “the” include plural referents unless the context clearly dictates otherwise. Approximating language, as used herein throughout the specification and claims, may be applied to modify a quantitative representation that could permissibly vary without resulting in a change in the basic function to which it is related. Accordingly, a value modified by a term such as “about” is not to be limited to the precise value specified. In some instances, the approximating language may correspond to the precision of an instrument for measuring the value. Moreover, unless specifically stated otherwise, a use of the terms “first,” “second,” etc., do not denote an order or importance, but rather the terms “first,” “second,” etc., are used to distinguish one element from another.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances an event or capacity can be expected, while in other circumstances the event or capacity cannot occur—this distinction is captured by the terms “may” and “may be.”

The best mode for carrying out the invention has been described for purposes of illustrating the best mode known to the applicant at the time and enable one of ordinary skill in the art to practice the invention, including making and using devices or systems and performing incorporated methods. The examples are illustrative only and not meant to limit the invention, as measured by the scope and merit of the claims. The invention has been described with reference to preferred and alternate embodiments. Obviously, modifications and alterations will occur to others upon the reading and understanding of the specification. It is intended to include all such modifications and alterations insofar as they come within the scope of the appended claims or the equivalents thereof. The patentable scope of the invention is defined by the claims, and may include other examples that occur to one of ordinary skill in the art. Such other examples are intended to be within the scope of the claims if they have structural elements that do not differentiate from the literal language of the claims, or if they include equivalent structural elements with insubstantial differences from the literal language of the claims.

What is claimed is:

1. A thermal leveler blank comprising:
a first encapsulating layer;
a second encapsulating layer arranged over the first encapsulating layer; and
a thermal spreader layer between the first encapsulating layer and the second encapsulating layer, wherein each of the first and second encapsulating layers have substantially planar outermost surfaces that are free of thermal control structures.

2. The thermal leveler blank of claim 1, wherein the first encapsulating layer and the second encapsulating layer have a lower thermal conductivity than the thermal spreader layer.

3. The thermal leveler blank of claim 1, wherein the first encapsulating layer and the second encapsulating layer are made of a plurality of layers bonded together.

4. The thermal leveler blank of claim 1, wherein the first encapsulating layer and the second encapsulating layer comprise at least one of: stainless steel, nickel or a nickel alloy, or aluminum or an aluminum alloy.

5. The thermal leveler blank of claim 1, wherein the thermal spreader layer comprises graphite.

6. The thermal leveler blank of claim 1, wherein the thermal spreader layer comprises diamond.

7. The thermal leveler blank of claim 1, wherein the thermal spreader layer comprises copper.

8. The thermal leveler blank of claim 1, wherein the first encapsulating layer is permanently bonded to the second encapsulating layer at a bonding interface.

9. The thermal leveler blank of claim 8, wherein the bonding interface laterally surrounds the thermal spreader layer.

10. The thermal leveler blank of claim 1, further comprising one or more support vias extending between the first and second encapsulating layers and through an opening in the thermal spreader layer, wherein the one or more support vias comprise a same material as at least one of the first or second encapsulating layers.

11. The thermal leveler blank of claim 1, wherein the first encapsulating layer has a first thickness arranged directly above the thermal spreader layer, wherein the thermal spreader layer has a second thickness, and wherein a ratio between the first thickness and the second thickness is between 0.5 and 4.

12. The thermal leveler blank of claim 1, wherein further comprising an interface layer that separates the thermal spreader layer from the first encapsulating layer and the second encapsulating layer.

13. The thermal leveler blank of claim 12, wherein the interface layer comprises chromium.

14. The thermal leveler blank of claim 12, wherein the interface layer comprises molybdenum.

15. The thermal leveler blank of claim 12, wherein the interface layer is absent at a bonding interface directly between the first encapsulating layer and the second encapsulating layer, wherein the bonding interface is arranged at a periphery of the thermal spreader layer.

16. The thermal leveler blank of claim 12, wherein the interface layer is absent on the vertical walls of the first and second encapsulating layer.

17. A thermal leveler blank comprising:
a first encapsulating layer having a bottommost surface that is substantially planar;
a second encapsulating layer arranged over the first encapsulating layer having a topmost surface that is substantially planar; and
a thermal spreader layer sandwiched between the first encapsulating layer and the second encapsulating layer, wherein outer sidewalls of the thermal spreader layer are surrounding by at least one of the first or second encapsulating layers, and wherein the thermal spreader layer has a greater thermal conductivity than that of the first and second encapsulating layers.

18. The thermal leveler blank of claim 17, wherein the first encapsulating layer is thicker than each of the second encapsulating layer and the thermal spreader layer.

19. The thermal leveler blank of claim 17, wherein the first encapsulating layer is permanently bonded to the second encapsulating layer at a bonding interface.

20. A method of forming a thermal leveler comprising:
forming a thermal leveler blank comprising:
providing a first encapsulating layer and a second encapsulating layer, wherein at least one of the first or second encapsulating layers comprise a recess,
aligning a thermal spreader layer within the recess of the at least one of the first or second encapsulating layers, and
bonding the first encapsulating layer to the second encapsulating layer at a first bonding interface such that the thermal spreader layer is sandwiched between and surrounded by the first and second encapsulating layers, and
machining the first encapsulating layer to form a pattern on a surface of the first encapsulating layer opposite to the thermal spreader layer; and
fitting a thermal control structure within patterned surface of the first encapsulating layer.

21. The method of claim 20, wherein the thermal control structure comprises a heating coil or cooling passages.

22. The method of claim 20, wherein the bonding of the first encapsulating layer to the second encapsulating layer is performed under a temperature and pressure to bond the first encapsulating layer to the second encapsulating layer.

23. The method of claim 20, wherein the second encapsulating layer is machined to accommodate handling and thermal control structures.

24. The method of claim 23, wherein the handling and thermal control structure include mesas or backside gas channels.

25. The method of claim 20, further comprising coupling a third encapsulating layer on the first encapsulating layer to sandwich the thermal control structure between the first and third encapsulating layers.

26. The method of claim 25, wherein the bonding of the first encapsulating layer to the second encapsulating layer is performed at a first temperature, and the coupling of the third encapsulating layer on the first encapsulating layer is performed at a second temperature less than the first temperature.

27. The method of claim 25, wherein the bonding of the first encapsulating layer to the third encapsulating layer is performed via welding.
